(19) United States
(12) Patent Application Publication
(10) Pub. No.: US 2024/0242939 A1
(43) Pub. Date: Jul. 18, 2024

(54) PLASMA-ASSISTED FILM REMOVAL FOR WAFER FABRICATION

(71) Applicant: Micron Technology, Inc., Boise, ID (US)

(72) Inventors: Chao Lin Lee, Singapore (SG); Rachmat Wibowo, Singapore (SG); Lipeng Qian, Singapore (SG); SAMUEL SISWANTO, Singapore (SG)

(21) Appl. No.: 18/404,542

(22) Filed: Jan. 4, 2024

Related U.S. Application Data
(60) Provisional application No. 63/438,993, filed on Jan. 13, 2023.

(51) Int. Cl. H01J 37/32

(52) U.S. Cl. CPC H01J 37/32449; H01J 37/32715; H01J 2237/3321; H01J 2237/3323; H01J 2237/3328; H01J 2237/3346

(57) ABSTRACT

Methods, systems, and devices for plasma-assisted film removal for wafer fabrication are described. The present disclosure provides in-situ techniques for removing a film from a select portion of a wafer, such as a surrounding bevel edge. After forming a film on the wafer using chemical vapor deposition (CVD), the wafer may be raised to a higher position in the chamber for CVD. A combination of gases may be ejected from a gas fixture and directed, respectively, to different portions of the wafer. The combination of gases may react to selectively remove the film from the bevel edge of the wafer and maintain the film on other portions of the wafer.

### CROSS REFERENCE

The present Application for Patent claims priority to and the benefit of U.S. Provisional Application No. 63/438,993 by Lee et al., entitled “PLASMA-ASSISTED FILM REMOVAL FOR WAFER FABRICATION,” filed Jan. 13, 2023, assigned to the assignee hereof, and is expressly incorporated by reference in its entirety herein.

### TECHNICAL FIELD

The following relates to one or more systems for memory, including plasma-assisted film removal for wafer fabrication.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 illustrates an example of a memory die that supports plasma-assisted film removal for wafer fabrication in accordance with examples as disclosed herein.

FIG. 2 illustrates an example of a manufacturing system that supports plasma-assisted film removal for wafer fabrication in accordance with examples as disclosed herein.

FIGS. 3A and 3B illustrate examples of manufacturing systems that support plasma-assisted film removal for wafer fabrication in accordance with examples as disclosed herein.

FIGS. 4A and 4B illustrate examples of manufacturing systems that support plasma-assisted film removal for wafer fabrication in accordance with examples as disclosed herein.

FIG. 5 illustrates an example of a process flow that supports plasma-assisted film removal for wafer fabrication in accordance with examples as disclosed herein.

FIG. 6 illustrates a flowchart showing a method or methods that support plasma-assisted film removal for wafer fabrication in accordance with examples as disclosed herein.

### DETAILED DESCRIPTION

Some wafers (e.g., for memory devices) are formed using a chemical vapor deposition (CVD) process. Specifically, within a vacuum chamber, a manufacturing system may apply a combination of gas and plasma to deposit (e.g., form) a film over the wafer (e.g., a semiconductor wafer, a substrate). However, the deposition of film on the wafer's edges (e.g., bevel edge) during CVD may complicate subsequent manufacturing processes. For example, etching the film (e.g., to expose portions of the wafer) may lead to defects (e.g., contamination) as the film peels off from the edges of the wafer. Further, techniques to prevent such defects across multiple chambers (e.g., ex-situ), may increase manufacturing costs and reduce efficiency. Preventing the deposition of film on the bevel edge (e.g., during CVD) may also lead to complications. For example, covering the bevel edge may lead to an uneven film near the bevel edge and reduce overall uniformity, among other issues.

The present disclosure provides techniques for removing deposited film from the bevel edge of a wafer inside the vacuum chamber (e.g., in-situ). For example, after forming the film using CVD, the wafer may be raised to a higher position within the chamber, and the manufacturing system may perform a film removal process. Specifically, combination of gases may be ejected from a gas fixture and directed, respectively, to different portions of the wafer (e.g., the center and the bevel edge). For example, a first gas may be directed toward the center of the wafer and a second gas (different than the first gas) may be directed toward the edges of the wafer. The combination of gases may react (e.g., with a plasma) to selectively remove the film from the bevel edge of the wafer while protecting the film on other portions of the wafer.

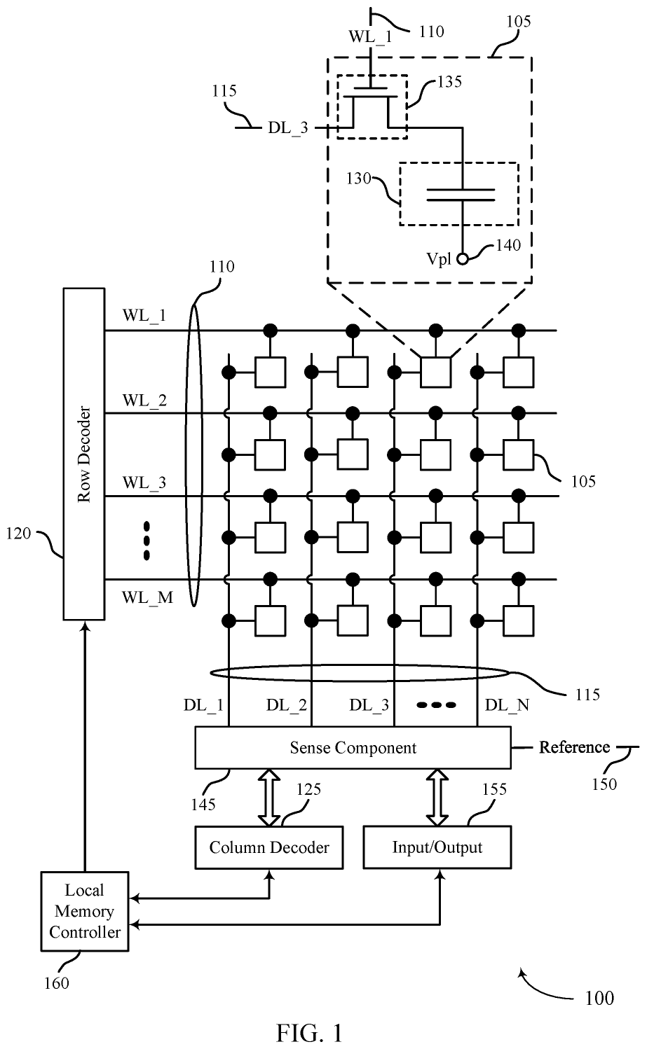

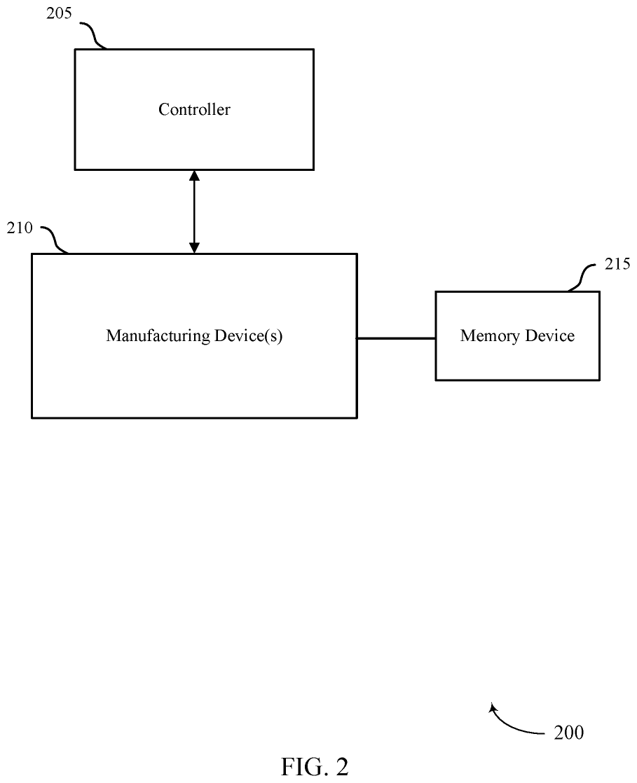

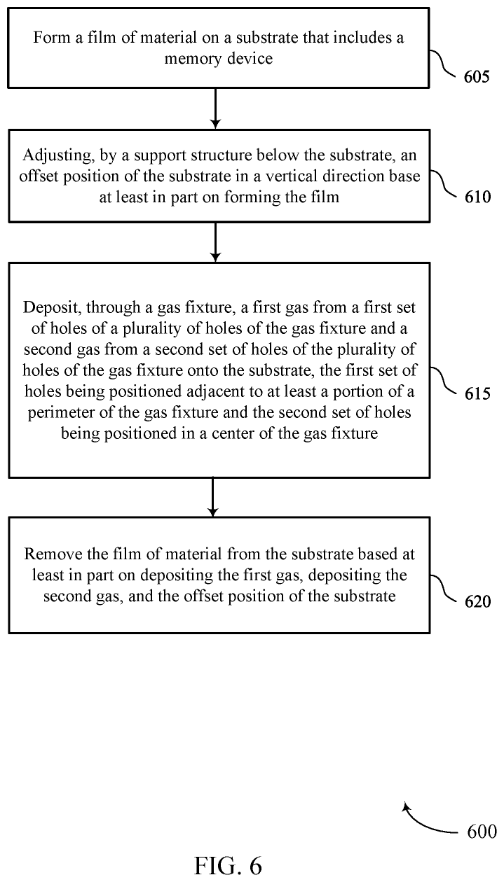

Features of the disclosure are initially described in the context of systems and dies as described with reference to FIG. 1. Features of the disclosure are described in the context of wafers and manufacturing systems as described as described with reference to FIGS. 2 through 5. These and other features of the disclosure are further illustrated by and described with reference to a flowchart that relates to plasma-assisted film removal for wafer fabrication as described with reference to FIG. 6.

FIG. 1 illustrates an example of a memory die 100 that supports plasma-assisted film removal for wafer fabrication in accordance with examples as disclosed herein. In some examples, the memory die 100 may be referred to as a memory chip, a memory device, or an electronic memory apparatus. The memory die 100 may include one or more memory cells 105 that may be programmable to store different logic states (e.g., programmed to one of a set of two or more possible states). For example, a memory cell 105 may be operable to store one bit of information at a time (e.g., a logic 0 or a logic 1). In some examples, a memory cell 105 (e.g., a multi-level memory cell) may be operable to store more than one bit of information at a time (e.g., a logic 00, logic 01, logic 10, a logic 11).

In some examples, a memory cell 105 may store a charge representative of the programmable states in a capacitor. DRAM architectures may include a capacitor that includes a dielectric material to store a charge representative of the programmable state. In other memory architectures, other storage devices and components are possible. For example, nonlinear dielectric materials may be employed. The memory cell 105 may include a logic storage component, such as capacitor 130, and a switching component 135 (e.g., a cell selection component). The capacitor 130 may be an example of a dielectric capacitor or a ferroelectric capacitor. A node of the capacitor 130 may be coupled with a voltage source 140, which may be the cell plate reference voltage, such as Vpl, or may be ground, such as Vss.

The memory die 100 may include access lines (e.g., word lines 110, digit lines 115) arranged in a pattern, such as a grid-like pattern. An access line may be a conductive line coupled with a memory cell 105 and may be used to perform access operations on the memory cell 105. In some examples, word lines 110 may be referred to as row lines. In some examples, digit lines 115 may be referred to as column lines or bit lines. References to access lines, row lines, column lines, word lines, digit lines, or bit lines, or their analogues, are interchangeable without loss of understanding. Memory cells 105 may be positioned at intersections of the word lines 110 and the digit lines 115.

Operations such as reading and writing may be performed on the memory cells 105 by activating access lines such as a word line 110 or a digit line 115. By biasing a word line 110 and a digit line 115 (e.g., applying a voltage to the word line 110 or the digit line 115), a single memory cell 105 may be accessed at their intersection. The intersection of a word line 110 and a digit line 115 in a two-dimensional or in a three-dimensional configuration may be referred to as an address of a memory cell 105. Activating a word line 110 or a digit line 115 may include applying a voltage to the respective line.

Accessing the memory cells 105 may be controlled through a row decoder 120, or a column decoder 125, or any combination thereof. For example, a row decoder 120 may receive a row address from the local memory controller 160 and activate a word line 110 based on the received row address. A column decoder 125 may receive a column address from the local memory controller 160 and may activate a digit line 115 based on the received column address.

Selecting or deselecting the memory cell 105 may be accomplished by activating or deactivating the switching component 135 using a word line 110. The capacitor 130 may be coupled with the digit line 115 using the switching component 135. For example, the capacitor 130 may be isolated from digit line 115 when the switching component 135 is deactivated, and the capacitor 130 may be coupled with digit line 115 when the switching component 135 is activated.

The sense component 145 may be operable to detect a state (e.g., a charge) stored on the capacitor 130 of the memory cell 105 and determine a logic state of the memory cell 105 based on the stored state. The sense component 145 may include one or more sense amplifiers to amplify or otherwise convert a signal resulting from accessing the memory cell 105. The sense component 145 may compare a signal detected from the memory cell 105 to a reference 150 (e.g., a reference voltage). The detected logic state of the memory cell 105 may be provided as an output of the sense component 145 (e.g., to an input/output 155), and may indicate the detected logic state to another component of a memory device (e.g., a memory device) that includes the memory die 100.

The local memory controller 160 may control the accessing of memory cells 105 through the various components (e.g., row decoder 120, column decoder 125, sense component 145). In some examples, one or more of the row decoder 120, column decoder 125, and sense component 145 may be co-located with the local memory controller 160. The local memory controller 160 may be operable to receive one or more of commands or data from one or more different memory controllers (e.g., an external memory controller associated with a host device, another controller associated with the memory die 100), translate the commands or the data (or both) into information that can be used by the memory die 100, perform one or more operations on the memory die 100, and communicate data from the memory die 100 to a host (e.g., a host device) based on performing the one or more operations. The local memory controller 160 may generate row signals and column address signals to activate the target word line 110 and the target digit line 115. The local memory controller 160 also may generate and control various signals (e.g., voltages, currents) used during the operation of the memory die 100. In general, the amplitude, the shape, or the duration of an applied voltage or current discussed herein may be varied and may be different for the various operations discussed in operating the memory die 100.

The local memory controller 160 may be operable to perform one or more access operations on one or more memory cells 105 of the memory die 100. Examples of access operations may include a write operation, a read operation, a refresh operation, a precharge operation, or an activate operation, among others. In some examples, access operations may be performed by or otherwise coordinated by the local memory controller 160 in response to various access commands (e.g., from a host device). The local memory controller 160 may be operable to perform other access operations not listed here or other operations related to the operating of the memory die 100 that are not directly related to accessing the memory cells 105.

The memory die 100 may be formed on a wafer (e.g., a substrate) for a memory device, as described herein. For example, in addition to removing deposited film from the bevel edge of a wafer, a manufacturing system may be configured to form the memory die 100 on the prepared wafer using one or more other manufacturing processes. In some examples, removing the deposited film from the bevel edge inside of a vacuum chamber (e.g., in-situ) may mitigate defects, lead to a more uniform and wafer for the subsequent manufacturing processes (e.g., the formation of memory die 100), and reduce overall manufacturing costs and time, among other benefits.

FIG. 2 illustrates an example of a manufacturing system 200 that supports plasma-assisted film removal for wafer fabrication in accordance with examples as disclosed herein. The manufacturing system 200 may include a controller 205 which may communicate with one or more manufacturing devices 210. The controller 205 may, for example, represent a manufacturing system controller or a controller for the manufacturing device(s) 210 (e.g., included in the manufacturing device(s) 210). Based on the communications between the controller 205 and the manufacturing device(s) 210, the manufacturing device(s) 210 may perform one or more fabrication techniques (e.g., on a memory device 215, which may be an example of a memory device described with reference to FIG. 1).

For example, the controller 205 may input information (e.g., manufacturing instructions or commands, fabrication processes) to the manufacturing device 210 via a connection (e.g., wired, wireless), and the manufacturing device 210 may transmit feedback information (e.g., an indication that an operation is complete) to the controller 205 via the same connection or another connection. In a further example, the manufacturing device 210 may perform one or more fabrication techniques (e.g., material depositing, material removal) on a memory device 215.

The manufacturing device 210 may perform various manufacturing operations on the memory device 215 during fabrication, based on communications with the controller 205. For example, the manufacturing device 210 may add (e.g., deposit) or remove (e.g., etch) various materials onto or from the memory device (e.g., onto a wafer, other materials, a portion of one or the other, or a combination of both).

In some examples, the manufacturing device 210 may include a support structure which may be used to support the substrate of a memory device. For example, the support structure may include a pedestal positioned on top of multiple pins (e.g., lift pins), and the substrate may be positioned on the pedestal. In such examples, this support structure may secure the memory device 215 during manufacturing operations and may enable consistent fabrication across the face of the memory device 215. In some examples, the controller 205, a controller within the manufacturing device 210, or a combination of both may reposition (e.g., vertically move) the lift pins of the support structure for respective fabrication operations. For example, the lift pins may be raised or lowered in order to raise or lower the substrate. In such examples, the controller 205 may command (e.g., instruct, indicate an operation to perform) a controller within the manufacturing device 210 to position the substrate to a position above (e.g., not in contact with) the pedestal.

In some examples, the manufacturing device 210 may include a gas fixture which may be used to deposit gaseous materials onto the memory device 215 (e.g., within a chamber). For example, the gas fixture may include multiple openings (e.g., holes). In some cases, the gas fixture may be referred to as a showerhead. The gas fixture may also include, or be coupled with, one or more gas lines. For example, a subset of the holes may be associated with a respective gas line, and a gas may flow through the gas line, to the subset of holes, and into the chamber. In some examples, both of the gas lines may carry the same gas to the gas fixture. Alternatively, each gas line may flow a different gas (e.g., concurrently). Based on the configuration of holes, the gas fixture may deposit a respective gas to a select portion of the chamber (e.g., a center, an edge, or both) aligned with the respective subset of holes (e.g., a group of holes in the center of the showerhead, a group of holes lining the edge of the showerhead, or the like). In such examples, the controller 205 may command a controller within the manufacturing device 210 to open or close the gas lines, turning the gas on or off. Additionally, the controller 205 may command the controller within the manufacturing device 210 to flow a particular gas. For example, before or during CVD, the controller may flow the same gas to both gas lines (e.g., deposit one gas into the chamber). Before or during a film removal procedure, the controller may flow a different gas to each gas lines (e.g., deposit multiple gasses into the chamber).

In accordance with examples disclosed herein, the manufacturing system 200 may support plasma-assisted film removal for wafer fabrication. For example, manufacturing system may include, within a chamber, a support structure with a pedestal and one or more lift pins, where the support structure may be equipped to raise or lower the lift pins in the vertical direction. Further, the manufacturing system may include a gas fixture with one or more gas lines and multiple holes for gas deposition into the chamber. A controller (e.g., a controller 205 or another controller) may configure the gas fixture to deposit a gas for film deposition (e.g., CVD) into the chamber. After the CVD, the controller may determine to adjust an offset for a position of the substrate above the pedestal. For example, the controller may raise the substrate via the associated pins in order to position the substrate at a desired height (relative to the pedestal) for one or more fabrication operations. Further, the controller may configure the gas fixture to deposit another gas (e.g., a combination of gasses) for film removal into the chamber.

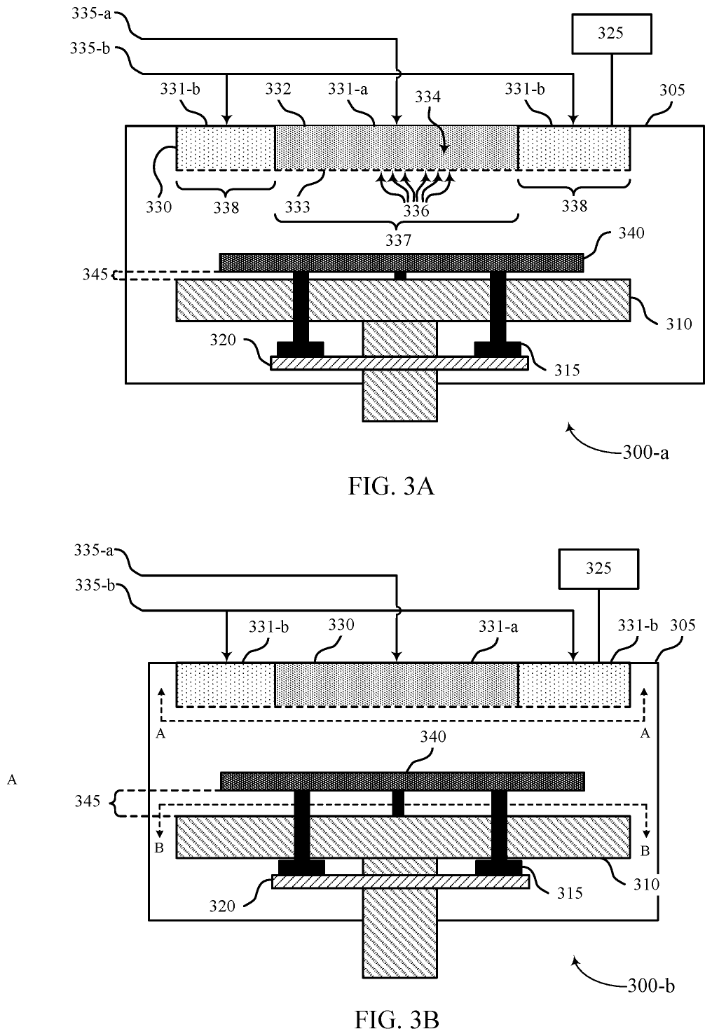

FIGS. 3A and 3B illustrate examples of manufacturing systems 300-a and 300-b that support plasma-assisted film removal for wafer fabrication in accordance with examples as disclosed herein. The manufacturing system 300-a and the manufacturing system 300-b each illustrate a side view of a same manufacturing system 300. For example, the manufacturing system 300-a illustrates a side view during a first manufacturing process (e.g., CVD) and the manufacturing system 300-b illustrates a side view during a second manufacturing process (e.g., film removal). The manufacturing system 300 may be used for fabrication of one or more aspects of a wafer, and may implement or be implemented by aspects of the manufacturing system 200 as described with reference to FIG. 2. For example, the manufacturing system 300 may be used for fabrication of one or more aspects of the memory die 100, or another memory device, as described with reference to FIG. 1. Additionally, or alternatively, the manufacturing system 300 may be used for fabrication of one or more aspects of another type of semiconductor wafer.

The manufacturing system 300 may include a controller (e.g., a controller 205 as described with reference to FIG. 2), a chamber 305 (e.g., that includes a vacuum), a support structure, a gas fixture 330 coupled with an RF power supply 325, and a wafer 340 (e.g., a memory device wafer, a substrate of the wafer). In some examples, the controller may be an example of a controller of a manufacturing device 210 described with reference to FIG. 2, a controller 205 described with reference to FIG. 2, or both, coupled with the support structure, the gas fixture, the chamber, or a combination thereof. In some examples, the wafer 340 may be an example of a substrate of a memory die 100 or a memory device 215, as described with reference to FIGS. 1 and 2, respectively. In some examples, the wafer 340 may be an example of a substrate of a semiconductor wafer to be used for one or more other semiconductor devices or circuits.

During some memory device manufacturing, a film deposition process may be performed on a wafer. For the film deposition, the wafer 340 may be transferred into a chamber 305, and positioned on the support structure within the chamber 305. The support structure may include a pedestal 310 (e.g., an electrostatic chuck (ESC)), lift pins 315 for supporting the pedestal 310, and a lift pin plate 320 for supporting the lift pins 315. In some examples, the support structure is configured to support the wafer 340 from below. For example, the wafer 340 may be positioned directly on the pedestal 310 and the lift pins 315 (e.g., flush with the pedestal 310), or may be positioned directly on the lift pins 315, at a height above the pedestal 310. Before or during the film deposition process, the controller may set (e.g., adjust, raise, or lower, relative to a starting position) the lift pins 315 to a first height such that the wafer 340 is a distance 345 from the pedestal 310. The support structure may be further adjustable in the vertical direction, and the controller may raise or lower the lift pins 315 to set the position of the wafer 340 for respective manufacturing processes.

To perform the film deposition process, the system may be configured to perform a CVD process on the wafer 340. The CVD process may be performed via the use of a plasma, a gas (e.g., a process gas), and an electric field inside of the chamber 305. The gas fixture 330 may include a section 331-a and a section 331-b, which may be coupled with a respective gas line 335-a and 335-b. Specifically, the section 331-a may be positioned in the center of a circular showerhead, and include a first subset of holes 337 in the showerhead. The section 331-b may be positioned radially around the section 331-a, and include a second subset of holes 338 adjacent to the outer edge (e.g., perimeter) of the showerhead. The gas fixture 330 may include a top wall 332 and a bottom wall 333. The top wall 332 may include inlets to receive gas from the gas lines 335 into the gas fixture 330. The bottom wall 333 may include a plurality of holes 336 configured to deliver the gases to the chamber 305. The gas fixture 330 may include a chamber 334 between the top wall 332 and the bottom wall 333 configured to distribute receive the gases from the gas lines 335 and distribute the gases to the holes 336 in the bottom wall 333. In some examples, the section 331-a may be divided from the section 331-b by a physical barrier configured to impede the flow of gas within the chamber 334. In some examples, the sections 331-a and 331-b in the chamber 334 may be configured based on the flows of gases from different gas lines. In such examples, increasing a first flow of a gas from a first gas line 335-a relative to a second flow of a gas from a second gas line 335-b may dynamically adjust the different sections of the gas fixture 330, where the holes 336 of each section 331-a and 331-b releases a particular gas from a particular gas line 335.

During the CVD process, the system may pre-heat the wafer, and the gas fixture may output (e.g., deposit) a first type of gas into the chamber 305 and on to the wafer 340. For example, both gas lines 335-a and 335-b may flow the same type of gas (e.g., including, inert gases, ammonia, nitrogen, carbon dioxide, or the like) to the first section 331-a and the second section 331-b, and into the chamber 305. When a plasma is emitted into the chamber 305 (e.g., concurrent with the gas), a reaction between the first type of gas and the plasma may form (e.g., deposit) a film of material over any exposed surfaces of the wafer 340. After the CVD process, and once the film is deposited, the system 300 may purge the chamber 305 to remove any byproducts, stabilize the chamber environment, adjust the pressure of the chamber environment, or the like.

The film deposition process may deposit the film on the edges (e.g., bevel edges) of the wafer 340, among other portions of the wafer 340. To remove the film from the bevel edges in-situ (e.g., in the same chamber 305), the system 300 may perform a second manufacturing process (e.g., a film removal process). Before or during the film removal process, the controller may set (e.g., adjust or raise relative to the first height) the lift pins 315 to a second height such that the wafer 340 is a distance 345 from the pedestal 310 is greater, as illustrated in FIG. 3B. In some examples, the second height may increase gas flow around the wafer 340, and result in a more thorough film removal. Additionally, or alternatively, adjusting the lift pins 315 to a second height may decrease the distance between the wafer 340 and the gas fixture 330, which may result in a more exact film removal.

During the film removal process, the gas fixture may deposit a first type of gas and a second type of gas into the chamber 305 and on to the wafer 340. For example, the gas lines 335-a may flow a first type of gas (e.g., the gas using during the CVD procedure, or another gas) to the first section 331-a and into the chamber 305. Concurrently, the gas line 335-b may flow a second type of gas (e.g., oxygen, fluorocarbon, or the like) that is different than the first type of gas. In some examples, the gas fixture 330 may be configured with a tunable gas flow ratio. For example, the ratio of gas flow from each respective first section 331-a and second section 331-b may increase or decrease, such that more or less gas flows from the second section 331-b on to the wafer. Likewise, as the gas flow from the second section 331-b increases, the gas flow from the first section 331-a may decrease, and vice versa. In some cases, the tunable gas flow ratio may be based on a density ratio between the two sections, a pressure ratio, a ratio of holes 337 to holes 338, or another feature. In some cases, the tunable gas flow ratio between the different gas lines 335 may result in the sections 331-a and 331-b being different sizes. For example, if the flow from the first gas line 335-a is higher than the flow from the second gas line 335-b, the section 331-a may get bigger and the section 331-b may get smaller. Conversely, if the flow from the second gas line 335-b is higher than the flow from the first gas line 335-a, the section 331-b may get bigger and the section 331-a may get smaller.

When a plasma is emitted into the chamber 305 (e.g., concurrent with the two gasses), multiple reactions may occur. For example, a first reaction between the first type of gas and the plasma may cover (e.g., maintain) the film of material over the adjacent portion of the wafer 340. A second reaction between the second type of gas and the plasma may remove (e.g., etch) an adjacent portion of the film. For example, the second section 331-b of the gas fixture may be positioned above the edge (e.g., perimeter) of the wafer 340 and the first section 331-a may be positioned above the center of the wafer 340. Based on this positioning, the gasses may flow onto particular portions of the wafer 340 which are aligned with the respective sections 331-a and 331-b. After the film removal process, the system 300 may purge the chamber 305.

The manufacturing system 300 may combine the film deposition process and the film removal process with one or more additional in-situ or ex-situ manufacturing processes. Once the in-situ manufacturing processes are complete, the wafer 340 may be transferred out of the chamber 305.

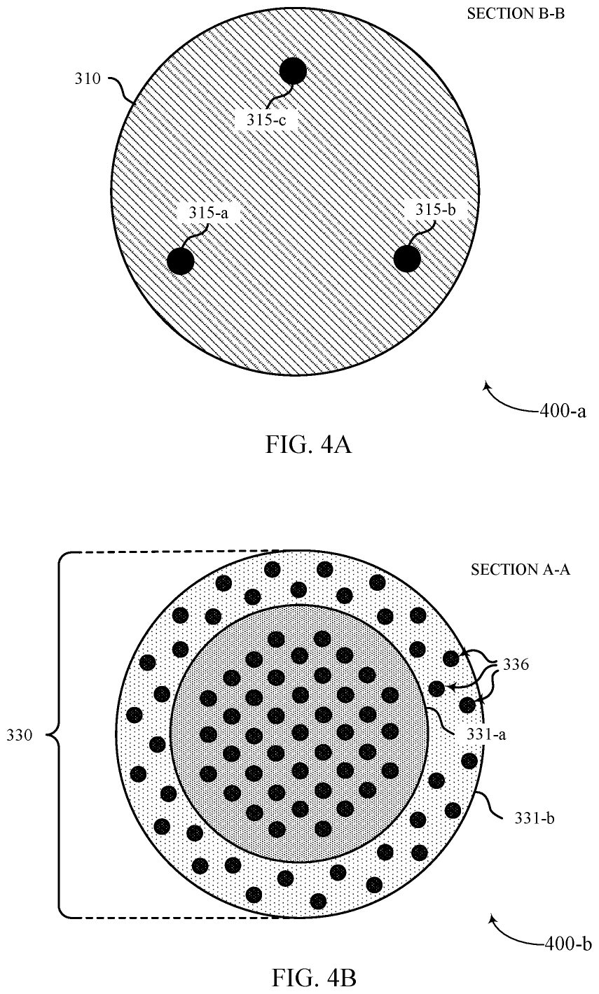

FIGS. 4A and 4B illustrate examples of manufacturing systems 400-a and 400-b that support plasma-assisted film removal for wafer fabrication in accordance with examples as disclosed herein. The manufacturing systems 400-a and 400-b may be used for fabrication of one or more aspects of a wafer, and may implement or be implemented by aspects of the manufacturing systems 200 and 300 as described with reference to FIGS. 2 and 3. For example, the manufacturing system 300 may be used for fabrication of one or more aspects of the memory die 100, or another memory device, as described with reference to FIG. 1. Additionally, or alternatively, the manufacturing systems 400-a and 400-b may be used for fabrication of one or more aspects of another type of semiconductor wafer.

The manufacturing system 400-a illustrates a top-down view B-B of the support structure, as illustrated by FIG. 3B. For example, the support structure may include the pedestal 310 and multiple lift pins 315. The lift pins may be equally or unequally distributed across (e.g., through) the face of the pedestal to provide even support to a wafer (e.g., wafer 340). Although the manufacturing system 400-a illustrates three lift pins 315-a, 315-b, and 315-c, the support structure may be configured with any quantity of lift pins 315. Additionally, the lift pins 315 may be configured in any configuration suited to a desired wafer. For example, the pedestal may be a circular form, and four or more lift pins 315 may be configured in a symmetric concentric form. In some cases, the lift pins 315 are flush with the pedestal 310. For example, a wafer 340 placed on the lift pins 315 may contact the pedestal 310 directly. Alternatively, the lift pins 315 may be raised out of the face of the pedestal 310. For example, as illustrated with reference to FIGS. 3A and 3B, a wafer 340 placed on the lift pins 315 may not contact the pedestal 310 directly. Rather, a gap may form between the pedestal 310 and the wafer 340, based at least in part on the height at which the lift pins 315 are set.

The manufacturing system 400-b illustrates a bottom-up view A-A of the gas fixture 330 (e.g., sections 331-a and 331-b) as illustrated by FIG. 3B. The gas fixture 330 may be illustrated as a showerhead configuration, with multiple openings (e.g., holes 336) for emitting gasses. The showerhead may be a circular form, as illustrated in FIG. 4B, with two sections. For example, the gas fixture 330 may include a section 331-a and a section 331-b, which may be coupled with a respective gas line 335-a and 335-b, and which may include a respective subset of holes 336. Specifically, the section 331-a may be positioned in the center of a circular showerhead, and include a first subset of holes 337, with reference to FIG. 3A. The section 331-b may be positioned radially around the section 331-a, and include a second subset of holes 338 adjacent to the outer edge (e.g., perimeter) of the showerhead, with reference to FIG. 3A. Although the manufacturing system 400-b illustrates a specific quantity of holes 336, the gas fixture 330, the section 331-a, the section 331-b, or a combination thereof, may include any quantity of holes 336. Additionally, each of the holes 336 may not be illustrated to scale, and may be configured with a smaller size or a larger size.

In addition to the configuration illustrated in FIG. 4B, the showerhead may be configured with a different ratio of the sections 331-a and 331-b. For example, the section 331-a may cover a smaller surface area of the showerhead relative to the section 331-b, the section 331-b may cover a smaller surface area of the showerhead relative to the section 331-a, or the surface areas may be equal. In some examples, the section 331-a may be off-centered within the showerhead. Additionally, or alternatively, and the section 331-b may not be evenly distributed around the perimeter of the showerhead. For example, a portion of the section 331-b may cover a thicker surface area than another portion of the section 331-b. In some examples, the section 331-b may not span the entire perimeter of the showerhead.

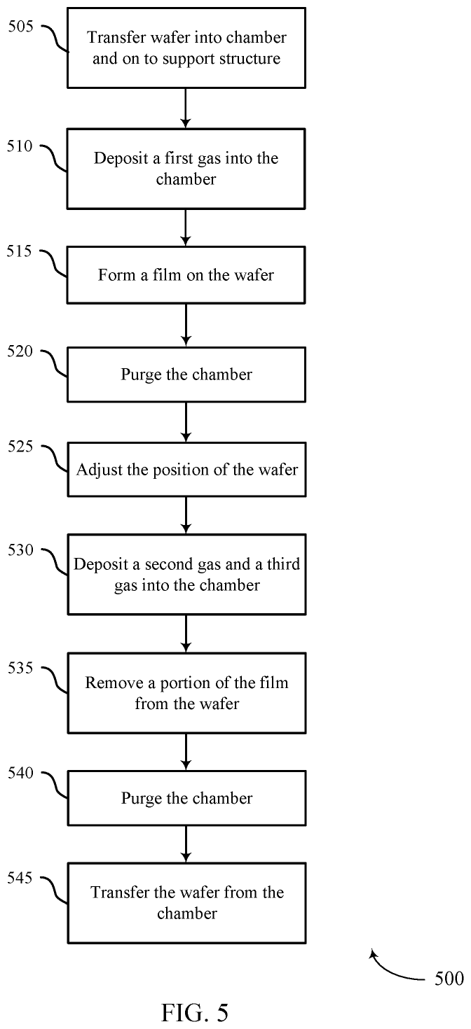

FIG. 5 illustrates an example of a process flow 500 that supports plasma-assisted film removal for wafer fabrication in accordance with examples as disclosed herein. The operations of process flow 500 may be implemented by a manufacturing system or one or more controllers associated with a manufacturing system as described herein. In some examples, one or more controllers may execute a set of instructions to control one or more functional elements of the manufacturing system to perform the described functions. Additionally, or alternatively, one or more controllers may perform aspects of the described functions using special-purpose hardware.

At 505, the manufacturing system transfers a wafer into a chamber for one or more manufacturing processes. In some cases, the transfer may be performed manually. Inside the chamber, the wafer is positioned on to a support structure configured for a first manufacturing procedure (e.g., CVD). For example, one or more lift pins of the support structure may be set to a first (e.g., lower) height above a pedestal of the support structure.

At 510, the manufacturing system may begin the first manufacturing procedure for film deposition. For example, a gas fixture configured inside of the chamber may deposit (e.g., emit, spray) a first gas into the chamber. The gas may surround or contact at least a portion of the wafer.

At 515, as part of the first manufacturing procedure, the manufacturing system may deposit a film on to the wafer. For example, once first gas is deposited into the chamber, the manufacturing system may apply a plasma, a pressure, a temperature, or a combination thereof, to react the plasma with the first gas. Due to the reaction, a film may form on the surface of the wafer, or a portion of the wafer (e.g., an exposed portion), including the bevel edges.

At 520, the manufacturing system may purge the chamber to remove byproducts, stabilize the chamber environment, adjust the pressure of the chamber environment, or a combination thereof.

At 525, the manufacturing system may adjust (e.g., set) the position of the support structure. For example, the lift pins of the support structure may be lifted to a second height (e.g., greater than the first height). Based on adjusting the support structure, a distance between the wafer and the pedestal of the support structure may be greater, relative to the distance between the wafer and the pedestal during the first manufacturing process. In some cases, a greater distance between the wafer and the pedestal may impact the flow of gas around the wafer during a second manufacturing process.

At 530, the manufacturing system may begin the second manufacturing procedure for film removal. For example, the gas fixture configured inside of the chamber may deposit (e.g., emit, spray) a second gas and a third gas into the chamber. Each respective gas may contact at least a portion of the wafer. For example, the gas fixture may emit the second gas from a subset of holes positioned in the center of the gas fixture. Accordingly, the second gas may contact a center portion of the wafer. Likewise, the gas fixture may emit the third gas from a subset of holes positioned along the perimeter of the gas fixture. Accordingly, the third gas may contact a perimeter (e.g., edge) portion of the wafer.

At 535, as part of the second manufacturing procedure, the manufacturing system may remove a portion of film from the wafer. For example, once the second and third gasses are deposited into the chamber, the manufacturing system may apply a plasma, a pressure, a temperature, or a combination thereof, to react the plasma with the second and third gasses. Due to the reaction, the portion of film in contact with the second gas may be preserved (e.g., maintained), and the portion of film in contact with the third gas (e.g., covering the bevel edges) may be removed.

At 540, the manufacturing system may purge the chamber for a second time.

At 545 the manufacturing system transfers a wafer out of the chamber for one or more additional manufacturing processes. In some cases, the transfer may be performed manually.

FIG. 6 shows a flowchart illustrating a method or methods 600 that supports plasma-assisted film removal for wafer fabrication in accordance with examples as disclosed herein. The operations of method 600 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 605, the method may include forming a film of material on a substrate that includes a memory device. The operations of 605 may be performed in accordance with examples as disclosed herein.

At 610, the method may include adjusting, by a support structure below the substrate, an offset position of the substrate in a vertical direction based at least in part on forming the film. The operations of 610 may be performed in accordance with examples as disclosed herein.

At 615, the method may include depositing, through a gas fixture, a first gas from a first set of holes of a plurality of holes of the gas fixture and a second gas from a second set of holes of the plurality of holes of the gas fixture onto the substrate, the first set of holes being positioned adjacent to at least a portion of a perimeter of the gas fixture and the second set of holes being positioned in a center of the gas fixture. The operations of 615 may be performed in accordance with examples as disclosed herein.

At 620, the method may include removing the film of material from the substrate based at least in part on depositing the first gas, depositing the second gas, and the offset position of the substrate. The operations of 620 may be performed in accordance with examples as disclosed herein.

In some examples, an apparatus (e.g., a manufacturing system) as described herein may perform a method or methods, such as the method 600. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for forming a film of material on a substrate that includes a memory device; adjusting, by a support structure below the substrate, an offset position of the substrate in a vertical direction based at least in part on forming the film; depositing, through a gas fixture, a first gas from a first set of holes of a plurality of holes of the gas fixture and a second gas from a second set of holes of the plurality of holes of the gas fixture onto the substrate, the first set of holes being positioned adjacent to at least a portion of a perimeter of the gas fixture and the second set of holes being positioned in a center of the gas fixture; and removing the film of material from the substrate based at least in part on depositing the first gas, depositing the second gas, and the offset position of the substrate.

Aspect 2: The method or apparatus of aspect 1, further including operations, features, circuitry, logic, means, or instructions, or any combination thereof for removing the film of material from a bevel edge of the substrate based at least in part on the first set of holes being positioned adjacent to the bevel edge of the substrate.

Aspect 3: The method or apparatus of aspects 1 through 2, where a first parameter of the first gas and a second parameter of the second gas are based at least in part on a tunable gas flow ratio between the first gas and the second gas.

Aspect 4: The method or apparatus of aspects 1 through 3, where adjusting the offset position of the substrate includes operations, features, circuitry, logic, means, or instructions, or any combination thereof for adjusting the support structure from a first position to a second position, where the second position is located above the first position in the vertical direction, and adjusting the offset position of the substrate is based at least in part on adjusting the support structure from the first position to the second position.

Aspect 5: The method or apparatus of aspects 1 through 4, further including operations, features, circuitry, logic, means, or instructions, or any combination thereof for depositing a third gas from the first set of holes of the gas fixture and from the second set of holes of the gas fixture onto the substrate and forming the film of material on the substrate based at least in part on depositing the first gas onto the substrate, where adjusting the offset position of the substrate is based at least in part on forming the film.

Aspect 6: The method or apparatus of aspects 1 through 5, further including operations, features, circuitry, logic, means, or instructions, or any combination thereof for applying a plasma to the substrate concurrent with depositing the first gas, the second gas, or both, where removing the film of material on the substrate is based at least in part on the plasma exciting the first gas.

Aspect 7: The method or apparatus of aspects 1 through 6, where the first gas, the second gas, or both include an oxygen-based gas or a fluorocarbon-based gas configured to remove the film.

Aspect 8: The method or apparatus of aspects 1 through 7, where the first gas includes an oxygen-based gas or a fluorocarbon-based gas configured to remove the film and the second gas includes an inert gas.

Aspect 9: The method or apparatus of aspects 1 through 8, where the second gas includes the first gas.

It should be noted that the methods described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 10: A system, including: a substrate including a memory device; a pedestal positioned below the substrate and configured to support the substrate as part of two or more fabrication processes performed on the memory device; a support structure positioned below the substrate and configured to adjust a height of the substrate relative to the pedestal as part of the two or more fabrication processes; and a gas fixture including a plurality of holes configured to deposit at least one gas associated with forming a material on the substrate as part of a first fabrication process of the two or more fabrication processes and at least two gasses associated with removing the material from the substrate as part of a second fabrication process of the two or more fabrication processes.

Aspect 11: The system of aspect 10, where the plurality of holes include: a first subset of holes of the plurality of holes positioned adjacent to at least a portion of a perimeter of the gas fixture; and a second subset of holes the plurality of holes positioned in a center of the gas fixture.

Aspect 12: The system of aspect 11, further including: a first gas line coupled with the first subset of holes and configured to provide gas output through a first set of holes; and a second gas line coupled with the second subset of holes and configured to provide gas output through a second set of holes.

Aspect 13: The system of any of aspects 11 through 12, where the first subset of holes are positioned adjacent to a second portion of a second perimeter of the substrate in a vertical direction based at least in part on the gas fixture being above the substrate.

Aspect 14: The system of any of aspects 10 through 13, further including: a first distance between the substrate and the pedestal associated with the first fabrication process of the two or more fabrication processes, where the first distance is based at least in part on a first height of the substrate relative to the pedestal; and a second distance between the substrate and the pedestal associated with the second fabrication process of the two or more fabrication processes, where the second distance is based at least in part on a second height of the substrate relative to the pedestal greater than the first height.

An apparatus is described. The following provides an overview of aspects of the apparatus as described herein:

Aspect 15: An apparatus, including: a pedestal configured to support a substrate as part of two or more fabrication processes performed on a device; a support structure configured to adjust a height of the substrate relative to the pedestal as part of the two or more fabrication processes; and a gas fixture including a plurality of holes configured to deposit at least one gas associated with forming a material on the substrate as part of a first fabrication process of the two or more fabrication processes and at least two gasses associated with removing the material as part of a second fabrication process of the two or more fabrication processes.

Aspect 16: The apparatus of aspect 15, where the plurality of holes include: a first subset of holes of the plurality of holes positioned adjacent to at least a portion of a perimeter of the gas fixture; and a second subset of holes the plurality of holes positioned in a center of the gas fixture.

Aspect 17: The apparatus of aspect 16, further including: a first gas line coupled with the first subset of holes and configured to provide gas output through a first set of holes; and a second gas line coupled with the second subset of holes and configured to provide gas output through a second set of holes.

Aspect 18: The apparatus of any of aspects 16 through 17, where the first subset of holes are positioned adjacent to a second portion of a second perimeter of the pedestal in a vertical direction based at least in part on the gas fixture being above the pedestal.

Aspect 19: The apparatus of any of aspects 15 through 18, where the support structure is configurable to adjust to a first height relative to the pedestal as part of the first fabrication process of the two or more fabrication processes and a second height for the second fabrication process of the two or more fabrication processes.

Aspect 20: The apparatus of aspect 19, where the second height is greater than the first height relative to the pedestal.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components, the controller affects a change that prevents signals from flowing between the components using a conductive path that previously permitted signals to flow.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component (e.g., a transistor) discussed herein may represent a field-effect transistor (FET), and may comprise a three-terminal component including a source (e.g., a source terminal), a drain (e.g., a drain terminal), and a gate (e.g., a gate terminal). The terminals may be connected to other electronic components through conductive materials (e.g., metals, alloys). The source and drain may be conductive, and may comprise a doped (e.g., heavily-doped, degenerate) semiconductor region. The source and drain may be separated by a doped (e.g., lightly-doped) semiconductor region or channel. If the channel is n-type (e.g., majority carriers are electrons), then the FET may be referred to as a n-type FET. If the channel is p-type (e.g., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over as one or more instructions (e.g., code) on a computer-readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and modules described in connection with the disclosure herein may be implemented or performed with a processor, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or any type of processor. A processor may also be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a computer, or a processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, digital subscriber line (DSL), or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. A method, comprising:
forming a film of material on a substrate that comprises a memory device;
adjusting, by a support structure below the substrate, an offset position of the substrate in a vertical direction based at least in part on forming the film;
depositing, through a gas fixture, a first gas from a first set of holes of a plurality of holes of the gas fixture and a second gas from a second set of holes of the plurality of holes of the gas fixture onto the substrate, the first set of holes being positioned adjacent to at least a portion of a perimeter of the gas fixture and the second set of holes being positioned in a center of the gas fixture; and
removing the film of material from the substrate based at least in part on depositing the first gas, depositing the second gas, and the offset position of the substrate.

2. The method of claim 1, wherein removing the film of material on the substrate comprises:
removing the film of material from a bevel edge of the substrate based at least in part on the first set of holes being positioned adjacent to the bevel edge of the substrate.

3. The method of claim 1, wherein a first parameter of the first gas and a second parameter of the second gas are based at least in part on a tunable gas flow ratio between the first gas and the second gas.

4. The method of claim 1, wherein adjusting the offset position of the substrate comprises:
adjusting the support structure from a first position to a second position, wherein the second position is located above the first position in the vertical direction, and adjusting the offset position of the substrate is based at least in part on adjusting the support structure from the first position to the second position.

5. The method of claim 1, further comprising:
depositing a third gas from the first set of holes of the gas fixture and from the second set of holes of the gas fixture onto the substrate; and
forming the film of material on the substrate based at least in part on depositing the first gas onto the substrate, wherein adjusting the offset position of the substrate is based at least in part on forming the film

6. The method of claim 1, further comprising:
applying a plasma to the substrate concurrent with depositing the first gas, the second gas, or both, wherein removing the film of material on the substrate is based at least in part on the plasma exciting the first gas.

7. The method of claim 1, wherein:
the first gas, the second gas, or both comprise a oxygen-based gas, or a fluorocarbon-based gas configured to remove the film.

8. The method of claim 1, wherein:
the first gas comprises an oxygen-based gas or a fluorocarbon-based gas configured to remove the film; and
the second gas comprises an inert gas.

9. The method of claim 1, wherein the second gas comprises the first gas.

10. A system, comprising:
a substrate comprising a memory device;
a pedestal positioned below the substrate and configured to support the substrate as part of two or more fabrication processes performed on the memory device;
a support structure positioned below the substrate and configured to adjust a height of the substrate relative to the pedestal as part of the two or more fabrication processes; and
a gas fixture comprising a plurality of holes configured to deposit at least one gas associated with forming a material on the substrate as part of a first fabrication process of the two or more fabrication processes and at least two gasses associated with removing the material from the substrate as part of a second fabrication process of the two or more fabrication processes.

11. The system of claim 10, wherein the plurality of holes comprise:
a first subset of holes of the plurality of holes positioned adjacent to at least a portion of a perimeter of the gas fixture; and
a second subset of holes the plurality of holes positioned in a center of the gas fixture.

12. The system of claim 11, further comprising:
a first gas line coupled with the first subset of holes and configured to provide gas output through a first set of holes; and
a second gas line coupled with the second subset of holes and configured to provide gas output through a second set of holes.

13. The system of claim 11, wherein the first subset of holes are positioned adjacent to a second portion of a second perimeter of the substrate in a vertical direction based at least in part on the gas fixture being above the substrate.

14. The system of claim 10, further comprising:
a first distance between the substrate and the pedestal associated with the first fabrication process of the two or more fabrication processes, wherein the first distance is based at least in part on a first height of the substrate relative to the pedestal; and
a second distance between the substrate and the pedestal associated with the second fabrication process of the two or more fabrication processes, wherein the second distance is based at least in part on a second height of the substrate relative to the pedestal greater than the first height.

15. An apparatus, comprising:
a pedestal configured to support a substrate as part of two or more fabrication processes performed on a device;
a support structure configured to adjust a height of the substrate relative to the pedestal as part of the two or more fabrication processes; and
a gas fixture comprising a plurality of holes configured to deposit at least one gas associated with forming a material on the substrate as part of a first fabrication process of the two or more fabrication processes and at least two gasses associated with removing the material as part of a second fabrication process of the two or more fabrication processes.

16. The apparatus of claim 15, wherein the plurality of holes comprise:
a first subset of holes of the plurality of holes positioned adjacent to at least a portion of a perimeter of the gas fixture; and
a second subset of holes the plurality of holes positioned in a center of the gas fixture.

17. The apparatus of claim 16, further comprising:
a first gas line coupled with the first subset of holes and configured to provide gas output through a first set of holes; and
a second gas line coupled with the second subset of holes and configured to provide gas output through a second set of holes.

18. The apparatus of claim 16, wherein the first subset of holes are positioned adjacent to a second portion of a second perimeter of the pedestal in a vertical direction based at least in part on the gas fixture being above the pedestal.

19. The apparatus of claim 15, wherein the support structure is configurable to adjust to a first height relative to the pedestal as part of the first fabrication process of the two or more fabrication processes and a second height for the second fabrication process of the two or more fabrication processes.

20. The apparatus of claim 19, wherein the second height is greater than the first height relative to the pedestal.
